(19) United States
(12) Patent Application Publication
(10) Pub. No.: US 2003/0127725 A1
(43) Pub. Date: Jul. 10, 2003

(54) Metal wiring board, semiconductor device, and method for manufacturing the same

(75) Inventors: Yasuhiro Sugaya, Toyonaka-shi (JP); Toshiyuki Asahi, Osaka-shi (JP); Satoru Yuhaku, Osaka-shi (JP); Seiichi Nakatani, Hirakata-shi (JP)

Correspondence Address: MERCHANT & GOULD PC, P.O. BOX 2903, MINNEAPOLIS, MN, 55402-0903, US

(73) Assignee: Matsushita Electric Industrial Co., Ltd., Kadoma-shi (JP)

(21) Appl. No.: 10/316,699

(22) Filed: Dec. 10, 2002

(30) Foreign Application Priority Data
Dec. 13, 2001 (JP) 2001-380009

(51) Int. Cl. H01L 23/053

(52) U.S. Cl. 257/700

(57) ABSTRACT

The present invention provides a metal wiring board in which metal wiring buried in a surface layer of an electrically insulating substrate is adhered to a carrier sheet covering the metal wiring that can be mechanically detached and that can prevent oxidation of the metal wiring. A semiconductor device that uses this substrate is structured so that a metal terminal electrode buried in an electrically insulating substrate is electrically connected to a protruding electrode on a semiconductor element, the protruding electrode has a structure wherein its tip is flattened by mounting the semiconductor element to the substrate, and the portion where the substrate and the semiconductor element are connected is reinforced by an insulating resin structure and formed into a single unit therewith. Thus, the present invention provides a metal wiring board that uses low-cost wiring patterns, is low resistance, and is provided with a carrier sheet with which highly reliable bump connection is possible, a semiconductor device, and a method of manufacturing the same.

### FIELD OF THE INVENTION

The present invention relates to metal wiring boards provided with a carrier sheet, to semiconductor devices, and to methods for manufacturing the same.

### BACKGROUND OF THE INVENTION

There is a growing demand for increasingly compact and high performance semiconductor devices, for example, as portable devices become smaller and more powerful. This requires that the number of terminal pins is increased in order to produce a more narrow pitch or area array. However, there are limitations to narrowing the pitch, and while on the one hand it is necessary that advances are made to narrow the pitch over what it is today, it is also essential that packaging is carried out providing pads over the elements or the wiring as well. One technology that is capable of this is called C4 (Controlled Collapse Chip Connection), which employs soldering bumps and was developed by IBM of the United States of America. In addition to soldering bumps, there are also other structures in which Au plated bumps are formed after a barrier metal is formed.

With these conventional technologies, terminal electrodes can be formed on the active elements of IC chips, and it can be anticipated that the active elements of the IC chip will not be harmed even if protruding electrodes are formed there.

On the other hand, at the same time there is a need for surface processing, such as Au plating, for wiring patterns including terminal electrodes on the substrate side that join with these protruding electrodes. The above-mentioned plating bumps and wiring patterns employ structures that are made of Au or Ni, for example, created through electroplating or electroless plating. Also, although hardly any pressure is required during packaging if soldering or a conductive adhesive (isotrophic) is used for the junction layer, when the junction layer is achieved by an anisotrophic conductive film (ACF), an insulating-film (NCF), or an anisotrophic conductive paste, for example, then a maximum pressure of about 20 g per pin may be required in order to ensure stable and reliable connections.

FIGS. 5A and 5B show a conventional mounting method in a case where an anisotrophic conductive film (ACF) is used. First electrodes 402 of a first substrate 401 are mounted to second electrodes 405 of a second substrate 406 via an anisotrophic conductive film (ACF) 407. Conductive particles 403 included in the anisotrophic conductive film (ACF) 407 may be Ni particles or balls that are coated with Au (or Ni—Au), for example. An epoxy-based resin can be used as an adhesive agent 404. With heat and pressure applied simultaneously, the first electrode 402 and the second electrode 406 are connected with the conductive particles 403 sandwiched between them. Alternatively, mounting pressure and ultrasonic waves are used together if protruding electrodes made of Au are Au-Au bonded to the Au surface of input/output terminal electrodes of a circuit board.

On the other hand, the limit to advances for increasing the component density through methods for mounting active components such as semiconductor chips to the surface layer of circuit boards have become apparent, and as a result, methods have been proposed for internally mounting semiconductor chips in recessed portions provided in the circuit board (JP H05-259372A, JP H11-103147A, JP H11-163249A). In this case, after the semiconductor chips are mounted inside the recessed portions, a sealing resin is applied to seal them and protect the connected portions and semiconductor chips.

However, substrates that have been employed in conventional inner via hole connection methods have been made of resin-based materials. Thus they have a low degree of thermal conductivity and an increased need for the release of heat generated from internally mounted components. As a consequence, one problem with conventional substrates was that heat could not be adequately dissipated, and this caused a drop in the reliability of modules with internally packaged circuit components.

In one example for solving this problem, proposals have been made for internally packaging circuit components such as semiconductor chips onto substrates having high heat conductivity (JP H11-220262A, JP 2001-244638A).

As described above, whereas increasingly compact and thin packaging configurations are pursued, the number of terminal pins will continue to grow, and there is a need for further improvements in performance. Also, in order to lower costs it has become necessary to increase the productivity of packaging processes above and beyond what has been achieved to date. Moreover, packing by thermocompression bonding, as represented by ACF and NCF, for example, has garnered attention as a way to increase throughput.

However, from the viewpoint of further improvements in productivity, that is, lowering costs, it is preferable that the wiring pattern including terminal electrodes on the substrate side continues to be made of copper electrodes. Copper, however, is easily oxidized, and thus normally an anti-oxidizing film is provided. Anti-oxidizing films are made of a silane coupling material layer, a chromate anti-oxidizing layer, or an Ni—Zn plating layer, for example, and prevent oxidation of the copper foil.

Due to such antioxidizing films, ordinarily, when semiconductor elements are packaged on copper foil using thermocompression bonding, the antioxidizing film, which has high electrical resistance, results in a high initial connection resistance per pin after packaging. On the other hand, if the wiring pattern is formed without an antioxidizing film and packaged using thermocompression bonding, then the wiring portions may be oxidized, which leads to considerable variation in the initial connection resistance. Consequently, in general, copper foil wiring portions including terminal electrodes must always be Au plated if a stable, low resistance connection is to be obtained.

However, Au plating is not preferable from the standpoint of increasing productivity and lowering costs.

Also, considering the case disclosed in JP 2001-244638A for achieving small size and high density by internally installing active components such as semiconductor chips into a circuit board, if the above mentioned concerns are taken into account, then Au plated wiring patterns must be formed not only at the wiring portions of the multilayer wiring portions but also at a plurality (two or more) of layers, and this can lead to further increases in costs.

On the other hand, if circuit components are packaged in multiple layers, then for the sake of reliability, a plurality of reflows must be carried out for each packaged circuit component. Conceivable problems arising from this include separation of the Ni plating that is formed below layers when the Au plating is formed.

### SUMMARY OF THE INVENTION

The present invention was achieved in order to solve these conventional problems, and it is an object thereof to provide a metal wiring board that uses low-cost wiring patterns, is low resistance, and is provided with a carrier sheet with which highly reliable bump connection is possible, a semiconductor device, and a method of manufacturing the same.

To achieve the above object, a metal wiring board of the present invention is characterized in that metal wiring buried in a surface layer of an electrically insulating substrate is adhered to a carrier sheet covering the metal wiring that can be mechanically detached and that is for preventing oxidation of the metal wiring.

A semiconductor device of the present invention is structured so that a metal terminal electrode buried in an electrically insulating substrate is electrically connected to a protruding electrode on a semiconductor element. The protruding electrode has a structure with its tip flattened by mounting the semiconductor element to the substrate, and the portion where the substrate and the semiconductor element are connected is reinforced by an insulating resin structure and formed into a single unit therewith.

A method of manufacturing a semiconductor device according to the present invention includes:

a step of bringing a transfer material in which a metal wiring pattern is formed on a carrier sheet into contact with an electrically insulating substrate and burying the metal wiring pattern in the substrate;

a step of preparing in a predetermined form an insulating resin structure for reinforcing a portion where the metal wiring pattern is connected to a protruding electrode formed on a semiconductor element;

a stripping step of stripping away the carrier sheet; and

a semiconductor mounting step of applying heat and pressure to the metal wiring pattern that is exposed in the stripping step to bring the tip of the protruding electrode into contact with the metal wiring pattern via the insulating resin structure, and subsequently applying heat and pressure to the wiring pattern and the protruding electrode to flatten the tip and connect the wiring pattern and the protruding electrode.

### BRIEF DESCRIPTION OF THE DRAWINGS

FIGS. 1A and 1B are cross sectional views showing the manufacturing steps for a semiconductor device according to Embodiment 1 of the present invention, and FIGS. 1C to 1E are cross sectional views showing manufacturing steps for a semiconductor device according to Embodiment 2.

FIGS. 2A and 2B are cross sectional views showing the manufacturing steps for a separate semiconductor device according to Embodiment 2 of the present invention.

FIGS. 3A and 3B are cross sectional views showing the manufacturing steps for a semiconductor device according to Embodiment 3 of the present invention.

FIG. 4 is a cross sectional view of the wiring layer of a substrate with internally mounted components according to Embodiment 4 of the present invention.

FIGS. 5A and 5B are cross sectional views schematically showing a method for mounting a conventional semiconductor device that uses an anisotrophic conductive film (ACF).

### DESCRIPTION OF THE PREFERRED EMBODIMENTS

In the present invention, the metal wiring pattern including terminal electrodes formed on the substrate side is attached to a carrier sheet that is formed through a transfer mold method without an anti-oxidizing film on its surface and that is for preventing oxidation of the metal wiring. Thus, even after transfer, the carrier sheet that forms the transfer material can be maintained until immediately prior to the packaging of semiconductor elements. Consequently, despite the fact that the surface of the metal wiring pattern is not processed, the carrier sheet keeps the copper foil from being oxidized, even after heating.

On the other hand, thermocompression bonding of semiconductor elements is carried out after the carrier sheet has been removed, and therefore the metal wiring pattern is slightly oxidized. Consequently, for this configuration, a packaging method in which sufficient packaging pressure is used to reinforce the portions of connection between protruding electrodes and a film, such as an NCF or ACF, to which wiring patterns are connected, is preferable. Thus, it is preferable that the protruding electrodes break through the thinly formed oxide layer and that their tips are ultimately crushed in the structure after packaging.

Also, according to the configuration of the semiconductor device, the connected portions are formed only by the junction between the metal terminal electrodes and bumps, and thus there are few changes over time caused by repeated thermal impact from reflow, for example. Thus, this is favorable for forming a semiconductor device with a structure in which the semiconductor elements are buried inside the substrate.

With a semiconductor device in which semiconductor elements are internally mounted in the substrate, the inner via hole connections are achieved through inner via holes that are formed in an electrically insulating substrate, and thus circuit components can be packaged at a high density. Also, because heat generated by the circuit components is dissipated quickly by inorganic filler, a highly reliable semiconductor device in which circuit components are internally mounted can be achieved. Furthermore, rewiring is easy, and structurally it is possible to form various types of LGA (land grid array) electrodes with few restrictions.

On the other hand, from the standpoint of productivity, it is preferable that the protruding electrodes formed in the semiconductor are formed through a plating method with which multiple electrodes can be formed at once instead of forming them using a wire bonding method.

The present invention is capable of providing metal wiring boards that use low-cost wiring patterns, are low resistance, and are provided with a carrier sheet with which highly-reliable bump connection is possible, semiconductor devices, and methods for manufacturing the same.

Hereinafter, the present invention will be explained in further detail using embodiments thereof.

Embodiment 1

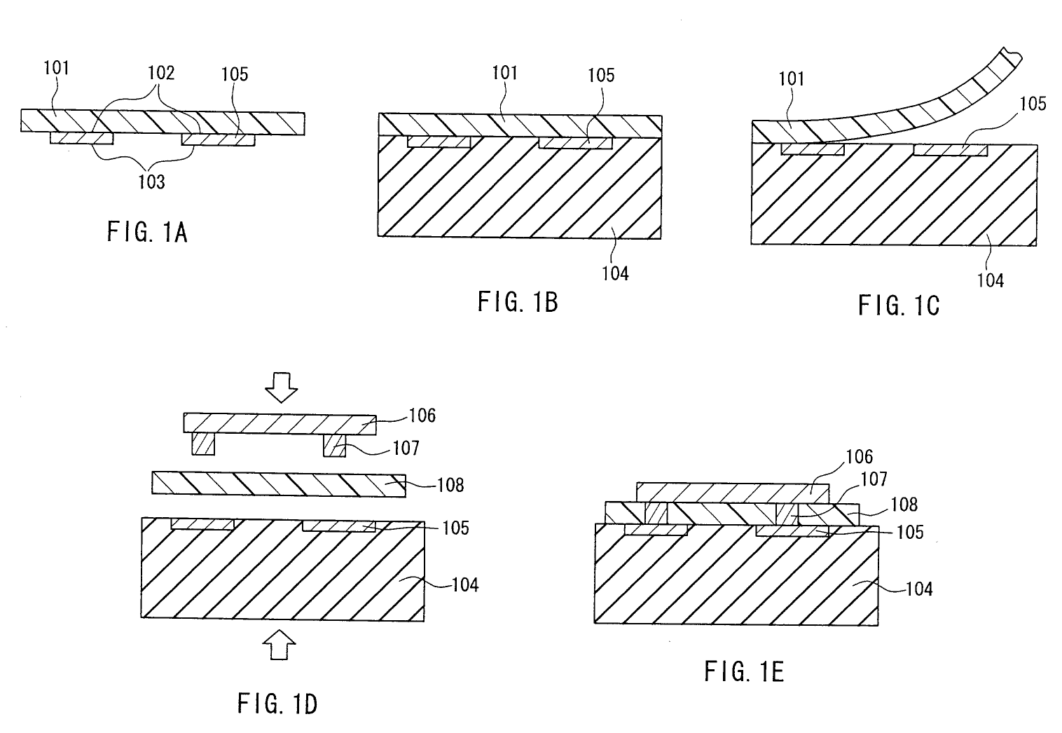

The present embodiment is an example of a substrate with carrier sheet of the present invention, and is schematically shown in FIGS. 1A and 1B.

As shown in FIG. 1A, a carrier sheet 101 and copper foil wiring patterns 105 on one surface of the carrier sheet 101 are provided as a transfer material. As for the copper foil wiring patterns, the surface of contact between the carrier sheet 101 and the wiring patterns 105 is a component mounting side 102, and the surface that is buried in the substrate is a burying side surface 103. It should be noted that in the following embodiments, “wiring patterns 105” refers collectively to terminal electrodes, wiring, and the like.

As shown in FIG. 1B, the substrate with carrier sheet is formed as a single unit including an electrically insulating substrate 104, the copper foil wiring patterns 105 buried in one principle face of the electrically insulating substrate 104, and the detachable carrier sheet 101 that covers the copper foil wiring patterns 105.

There are no limitations to the electrically insulating substrate 104 that is used in the present embodiment, and its scope is inclusive of glass-epoxy substrates such as FR-4 (substrates where epoxy resin is impregnated in glass fiber cloth), composite substrates made of a mixture of inorganic filler and resin, and ceramic substrates that can be sintered together with copper, such as glass ceramic substrates.

It should be noted that it is preferable that an anti-oxidizing film or the like, that is as thin as possible is formed on the substrate burying side surface 103 of the copper foil wiring patterns 105. In one example of the anti-oxidizing process, the anti-oxidizing film is formed at a weight of 0.05 to 0.5 mg/dm² per unit area through chromate processing, Zn plating, or silane coupling, for example. The component mounting side 102 is preferably the surface of the copper foil that is not processed.

According to this embodiment, the component mounting side 102, that is, the non-processed copper foil surface, whose original surface state is unstable, is covered by the detachable carrier sheet, and thus it can be maintained in a stable state without being oxidized.

In addition, the carrier sheet can be mechanically stripped when necessary, such as when components are mounted, which is convenient. However, if a chemical method such as etching is used to strip away the carrier sheet, then the component mounting side 102, that is, the non-processed copper foil surface, may be oxidized during the cleaning and drying steps, which may cause problems.

For the copper foil that is used as the copper foil wiring patterns 105, copper foil with a thickness of about 9 to 35 μm fabricated by electroplating, for example, can be used. To improve adhesion between the copper foil and the electrically insulating substrate 104, the contact surface between it and the electrically insulating substrate 104 ideally has been provided with an average roughness Ra of 1 μm or more. In addition, in order to increase the copper foil's adhesiveness and resistance to oxidation, its surface is preferably made of a silane coupling material layer, a chromate anti-oxidizing layer, or a Ni—Zn plating layer, for example. Alternatively, the surface of the copper foil can be solder plated with an Sn—Pb alloy or a lead-free, Sn—Ag—Bi based solder.

The wiring patterns that are formed on the principle face in the present invention are formed by transfer, and thus are buried in the substrate.

For the detachable carrier sheet 101, it is possible to use a synthetic resin film, for example polyimide, polyethylene terephthalate, polyethylene naphthalate, polyphenylene sulfite, polyethylene, polypropylene, or a fluoride resin. Alternatively, a suitable organic film can be coated and used as the detachable layer. The preferable thickness of the carrier sheet is 30 to 100 μm. A fluoride resin is for example poly-tetrafluoroethylene (PTFE), a copolymer of tetrafluoroethylene and perfluoroalkyl vinyl ether (PFA), a copolymer of tetrafluoroethylene and hexafluoropropylene (FEP), polyvinyl fluoride, or polyvinylidene fluoride.

If a metal foil, for example a copper foil, having a thickness of 30 μm or more is employed on the carrier sheet 101, then the copper foil wiring patterns can be formed via a metal plating layer such as a Cr plating layer or a Ni plating layer.

The wiring patterns 105 can be formed through photolithography and etching after the copper foil has been adhered to the carrier sheet 101, for example. By doing this, the surface of the copper foil after the carrier sheet is stripped away can be made cleaner than if a resin film is used as the carrier. That is, an anoxidized copper foil interface with luster can be exposed because the electroplating interface is directly exposed.

According to the substrate with carrier sheet presented in this embodiment, the wiring layer is covered by the carrier sheet, and thus oxidization of the wiring layer surface can be prevented and the substrate can be employed as a multilayer substrate with excellent storage stability. Consequently, it can be provided as a substrate for mounting circuit components, and in particular semiconductors, and this is beneficial.

Embodiment 2

This embodiment is an example of a semiconductor device of the present invention. FIGS. 1C to 1E are cross sectional views showing the semiconductor device according to this embodiment.

As shown in FIG. 1E, the semiconductor device of this embodiment includes an electrically insulating substrate 104, copper foil wiring patterns 105 that are formed buried in a principle face of the electrically insulating substrate 104, a resin film 108 that is formed into a single unit with the wiring patterns 105, a semiconductor element 106 that is disposed above the electrically insulating substrate 104, and bumps 107 that electrically connect the wiring patterns 105 and the semiconductor element 106.

With the semiconductor device of this embodiment, immediately after the carrier sheet 101 is stripped from the electrically insulating substrate 104, as shown in FIG. 1C, the film 108, which includes a resin component, is disposed on the copper foil wiring pattern 105 side of the electrically insulating substrate 104, as shown in FIG. 1D, the bumps 107, which are electrically connected to the semiconductor element 106, are disposed on the film 108, the copper foil wiring patterns 105 and the bumps 107 are aligned, and then heat and pressure are applied from above and below to join them. As for the heating and pressing conditions, it is preferable that a pressing force of 1.47×10⁶ Pa (15 kg/cm²) to 9.8×10⁶ Pa (100 kg/cm²) is applied at a temperature of 80 to 200° C.

The film 108 including a resin component is an insulating film (NCF), and should be a film with thermosetting resin as a principle component. It can be a mixture of inorganic filler and thermosetting resin. In this case it is preferable that heat and weight are applied to the film simultaneously so that it tightly fastens and connects the bumps 107 and the copper foil wiring patterns 105. The thermosetting resin is for example epoxy resin or phenolic resin.

For the inorganic filler, it is possible to use Al₂O₃, MgO, BN, AlN, or SiO₂, for example. It is preferable that the inorganic filler is packed at a high density in a range of 50 volume percent to 75 volume percent. Also, it is preferable that the average particle diameter of the inorganic filler is within a range of 0.1 μm to 40 μm. Furthermore, it is preferable that the thermosetting resin is epoxy resin, which has high thermal resistance, phenolic resin, cyanate resin, or polyphenylene ether resin, and it is particularly preferable that it is epoxy resin, because epoxy resin has high thermal resistance. It should be noted that the mixture further can include a diffusing agent, a coloring agent, a coupling agent, or a detaching agent.

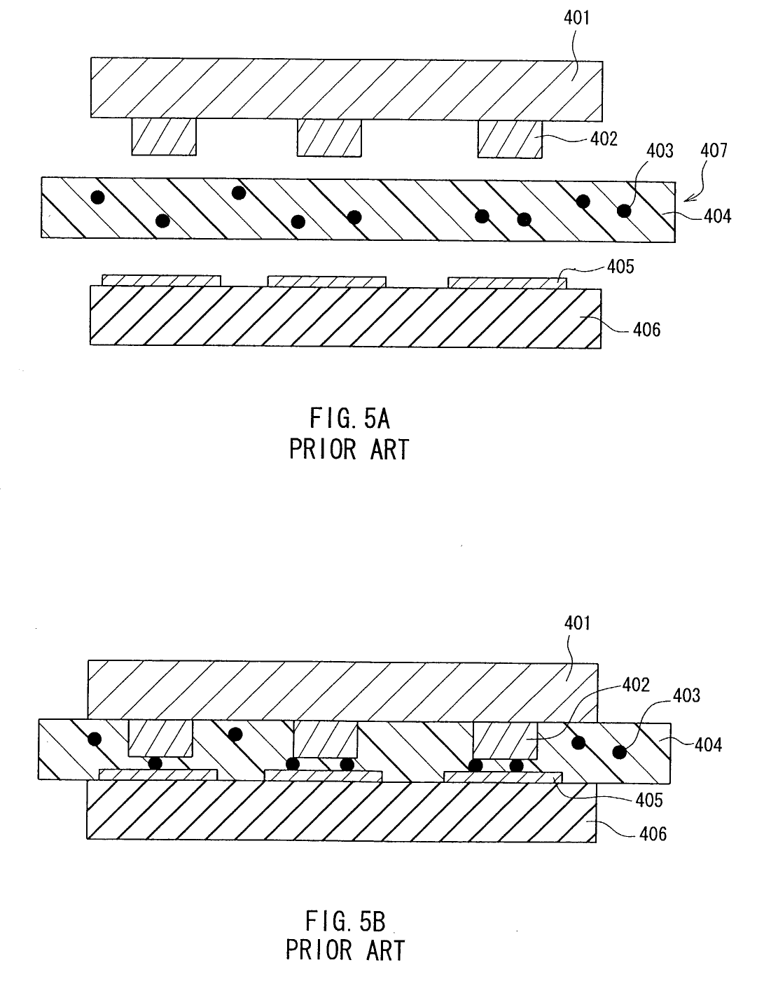

Alternatively, the film 108 including a resin component can be a film known as an anisotrophic conductive film (ACF), such as the film 407 shown in FIG. 5A. For anisotrophic conductive particles, it is possible to use Ni particles or resin balls that have been coated with Au (or Ni and Au). In this case as well, an epoxy resin, for example, can be used as the adhesive film, and heat and pressure can be applied simultaneously so as to connect the bumps 107 and the copper foil wiring patterns 105 by sandwiching the conductive particles between them.

Also, the present invention is not limited to a film including an insulating resin, and as long as it is an insulating resin structure, then an insulating resin can be employed in paste form rather than in film form. Furthermore, to prevent the surface of the film 108 including a resin component from becoming contaminated, it can be covered by a mold-release film until immediately before it is used, and then the mold-release film can be removed immediately before the semiconductor element 106 and the wiring patterns 105 are made into a single unit.

It is preferable that the bumps 107 are configured as protruding because the must penetrate the film. The bumps 107 can for example be metal bumps, formed as Au stud bumps by a wire bonding method in which an Au wire is used. Alternatively, taking productivity into account, they can be formed through a method in which numerous bumps are fabricated at once, such as a plating bump method, in which case bumps with a Cu—Ni—Au structure can be formed. However, bumps that are formed through plating normally are not very prominent, and thus their ability to penetrate the film 108 including a resin component is slightly diminished. Consequently, by using an ACF with conductive particles as filler, the junction between the plating bumps and the non-processed copper foil terminal electrodes can be achieved more reliably via the conductive particles.

On the other hand, if the bumps 107 are electrodes with a two-layered protrusion, then the top protrusion is sharp and thus easily can penetrate the film 108 including a resin component, so that an inorganic filler can be included in the film. Also, with the present configuration, the protruding electrodes are flattened by the wiring patterns 105 during packaging, and thus the thin oxide film that is formed on the non-processed copper foil surface during packaging and heating can be penetrated easily, and a favorable connection between the bumps 107 and the wiring patterns 105 can be attained.

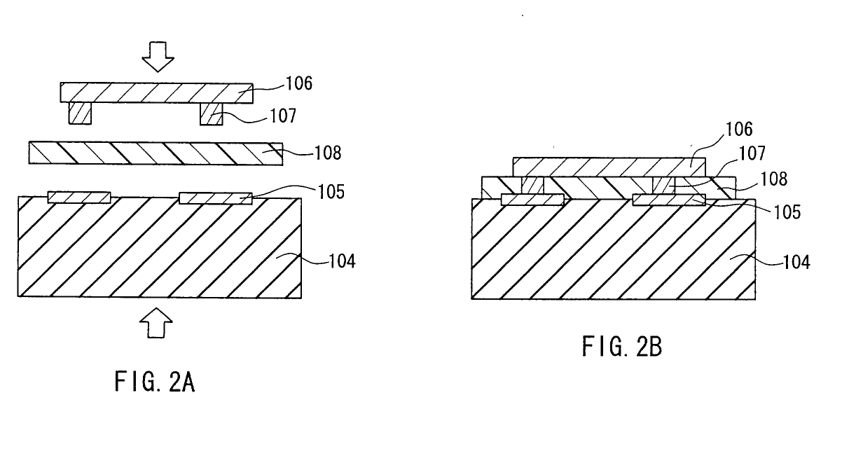

It should be noted that FIGS. 1A to 1E show examples of the metal wiring buried in which the surface of the wiring patterns 105 and the surface of the electrically insulating substrate 104 are level, but as shown in FIG. 2A, the wiring patterns 105 can protrude from the surface of the electrically insulating substrate 104. As shown in FIG. 2B, the film 108 including a resin component is interposed between the semiconductor element 106 and the electrically insulating substrate 104 and together these form a single unit, so that a favorable connection between the bumps 107 and the wiring patterns 105 is obtained.

Also, in the present embodiment, a case was described in which the bumps 107 and the wiring patterns 105 are directly joined, but the bumps 107 and the wiring patterns also can be joined via a conductive paste. One method for joining via a conductive paste is known as stud bump bonding (SBB). When this method is used, the weight that must be applied to form a junction between the bumps 107 and the wiring patterns 105 is small, and thus damage incurred by the semiconductor element can be reduced further.

Further, the semiconductor element can be a transistor, an IC, or an LSI, for example.

Embodiment 3

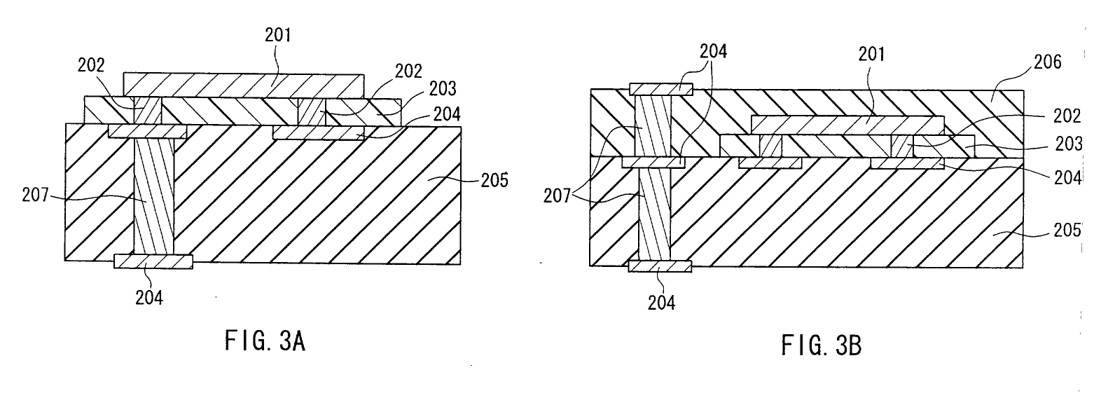

The present embodiment is an example of another semiconductor device. FIGS. 3A and 3B are cross sectional views showing the semiconductor device according to the present embodiment.

The semiconductor device of the present embodiment is a single unit including an electrically insulating substrate 205, copper foil wiring patterns 204 that are buried in one principle face and the other principle face of the electrically insulating substrate 205, an insulating resin portion 203 formed integrally with the wiring patterns 204 and including a resin component, a semiconductor element 201 disposed above the electrically insulating substrate 205, and bumps 202 for electrically connecting the wiring patterns 204 and the semiconductor element 201 (see FIG. 3A). Moreover, the semiconductor element 201, including the packaging portion, may be buried in an electrically insulating substrate 206, and the wiring patterns 204 connected to the buried semiconductor element 201 may be drawn out to the other surface layer via inner via holes 207 (see FIG. 3B).

It should be noted that when the semiconductor element is buried in the electrically insulating substrate, the semiconductor element is not packaged by providing recessed portions like in the conventional technologies described in the prior art section, and thus there are no gaps between the semiconductor element and the substrate.

Consequently, with the semiconductor device of the present embodiment, circuit components such as the semiconductor element 201 can be packaged with high density.

Apart from the electrically insulating substrate 206 and the inner via holes 207, the various configurations of the present embodiment are identical to those of Embodiment 1 and Embodiment 2, and thus description thereof is omitted.

The inner via holes 207 are made of material that is both thermosetting and conductive. For this thermosetting and conductive material, it is possible to use a conductive resin composition in which metal particles and thermosetting resin have been mixed, for example. The metal particles can be gold, silver, copper, or nickel, for example. Gold, silver, copper, and nickel are preferable because they have high conductivity, and copper is particularly preferable because it has high conductivity and a low degree of migration. For the thermosetting resin, it is possible to use epoxy resin, phenolic resin, cyanate resin, or polyphenylene ether resin, and it is particularly preferable that epoxy resin is used because of its high thermal resistance.

On the other hand, the electrically insulating substrate 206 is made of a mixture including inorganic filler and thermosetting resin.

For the inorganic filler, it is possible to use Al₂O₃, MgO, BN, AlN, or SiO₂, for example. It is preferable that the inorganic filler is packed at a high density, for example in a range of 60 weight percent to 90 weight percent. Also, it is preferable that the average particle diameter of the inorganic filler is within a range of 0.1 μm to 40 μm. Furthermore, it is preferable that the thermosetting resin is epoxy resin, which has high thermal resistance, phenolic resin, cyanate resin, or polyphenylene ether resin, and it is particularly preferable that it is epoxy resin because epoxy resin has high thermal resistance. It should be noted that the mixture further can include a diffusing agent, a coloring agent, a coupling agent, or a mold-release agent.

According to this embodiment, the electrically insulating substrate 206 does not include reinforcing material such as glass fiber, and thus circuit components easily can be buried in it.

Also, the semiconductor element 201 that is buried in the electrically insulating substrate 206 becomes a module with an internally mounted circuit component, and heat that is generated by the circuit component in the module with an internally mounted circuit component is quickly transferred by the inorganic filler included in the electrically insulating substrate 206. Consequently, a module with an internally mounted circuit component that is highly reliable can be achieved.

Also, the linear expansion coefficient, the thermal conductivity, and the dielectric constant, for example, of the electrically insulating substrate 206 can be controlled easily by the selection of the inorganic filler in the electrically insulating substrate 206. If the linear expansion coefficient of the electrically insulating substrate 206 can be made close to that of the semiconductor element, then the occurrence of cracks, for example, due to temperature changes can be prevented, and thus a circuit module that is highly reliable can be achieved. Moreover, by increasing the thermal conductivity of the electrically insulating substrate 206, a circuit component installed module that is highly reliable can be achieved, even if the circuit components are packaged at a high density. Furthermore, by lowering the dielectric constant of the electrically insulating substrate 206, a module for a high frequency circuit that has little dielectric loss can be achieved. Further, the semiconductor element 201, which is a circuit component, is blocked from outside air by the electrically insulating substrate 206, and thus a drop in reliability due to humidity can be prevented.

With the present embodiment, a layered structured of the electrically insulating substrates 205 and 206 is adopted, and thus from the standpoint of bending and warping, it is preferable that the electrically insulating substrate 205 and the electrically insulating substrate 206 share an identical composition.

Embodiment 4

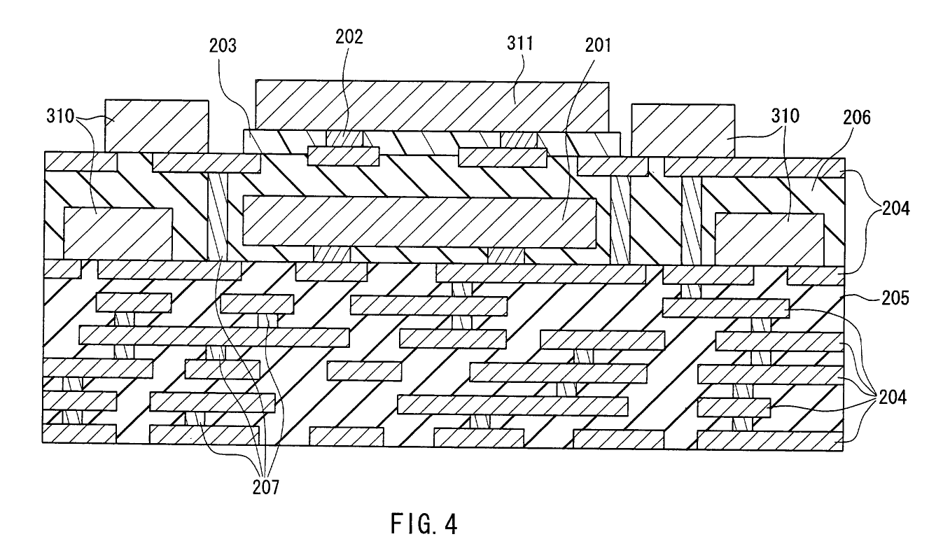

Next, a modified example of Embodiment 3 is shown in FIG. 4.

In FIG. 4, parts that are identical to those in FIG. 3 have been assigned identical numerals. In this modified example, a separate semiconductor element 311 and electrical components 310 are mounted onto the electrically insulating substrate 206. Also, other electrical components 310 are installed inside the electrically insulating layer. Other electrical components may be mounted or internally mounted in the same way as these.

It should be noted that in this modified example the electrically insulating substrate 205 is illustratively shown as a multilayer wiring substrate, and in the other embodiments as well a multilayer wiring substrate can be employed as the electrically insulating layer.

Also, in the above-mentioned embodiments, the electrical components can be chip components such as capacitors, inductors, and resistors, or diodes, thermistors, or switches, for example.

Furthermore, in the above-mentioned embodiments, the carrier film made of the transfer material can be copper foil and the detachable layer between the carrier sheet and the copper foil wiring patterns can be formed by a chrome plating layer. This has the benefit of making stripping even easier.

Further, in the above-mentioned embodiments, copper foil was used for the wiring patterns, but there are no limitations to this in the present invention, and the wiring patterns can also be a metal foil of aluminum, nickel, or the like.

### EXAMPLE

Hereinafter, the present invention will be described in further detail through a specific working example.

### Working Example 1

This working example describes an example of the fabrication method of the electrically insulating substrate made of a mixture including two components, an inorganic filler and a thermosetting resin, when fabricating the semiconductor devices corresponding to Embodiments 1 to 3.

The fabrication method of this working example is carried out in the following order. It starts with a method for fabricating an electrically insulating substrate, then proceeds to a method for fabricating the transfer mold material shown in FIG. 1A, a method for fabricating the substrate with carrier shown in FIG. 1B, a method for fabricating a semiconductor device with surface mounting shown in FIGS. 1C to 1E, and lastly, fabrication is completed with a method for manufacturing the substrate integrated semiconductor device shown in FIG. 3, in which the semiconductor element is provided internally within the substrate. Thus, the following description will follow this order.

In this working example, the epoxy resin “WE-2025” (trade name) made by Nippon Pelnox Corporation is used as liquid epoxy resin, “Phenolite VH4150” (trade name) made by Dainippon Ink and Chemicals Inc. is used as phenolic resin, and the cyanate resin “AroCy, M-30” (trade name) made by Asahi Chiba Co., Ltd. is used as cyanate resin. Also, either carbon black or a diffusing agent is added as an additive. Table 1 shows the conditions and Table 2 shows the results.

TABLE 1

| | Inorganic Filler | | Thermosetting Resin | | Other Additives | |
|---|---|---|---|---|---|---|
| Sample | | Additive % | | Additive % | | Additive % |
| No. | Type | (wt %) | Type | (wt %) | Type | (wt %) |
| 1 | Al₂O₃ | 60 | liquid epoxy resin | 39.8 | carbon black | 0.2 |
| 2 | Al₂O₃ | 70 | liquid epoxy resin | 29.8 | carbon black | 0.2 |
| 3 | Al₂O₃ | 80 | liquid epoxy resin | 19.8 | carbon black | 0.2 |
| 4 | Al₂O₃ | 85 | liquid epoxy resin | 14.8 | carbon black | 0.2 |
| 5 | SiO₂ | 83 | liquid epoxy resin | 16.5 | carbon black | 0.2 |
| 6 | SiO₂ | 86 | liquid epoxy resin | 13.5 | carbon black | 0.2 |
| 7 | MgO | 78 | liquid epoxy resin | 21.8 | carbon black | 0.2 |
| 8 | BN | 77 | liquid epoxy resin | 22.8 | carbon black | 0.2 |
| 9 | AlN | 85 | liquid epoxy resin | 14.8 | carbon black | 0.2 |
| 10 | SiO₂ | 75 | liquid epoxy resin | 24.8 | carbon black | 0.2 |
| 11 | Al₂O₃ | 90 | phenolic resin | 9.8 | carbon black | 0.2 |
| 12 | Al₂O₃ | 90 | cyanate resin | 9.8 | diffusing | 0.2 |
| | | | | | agent | |

(Remarks)
Al₂O₃: “SA-40” (trade name) made by Showa Denko K.K.
SiO₂: first grade reagent made by Kanto Kagaku K.K.
AlN: made by Dow Corning
BN: made by Denki Kagaku Kogyo K.K.
MgO: first grade reagent made by Kanto Kagaku K.K.
liquid epoxy resin: “WE-2025” (trade name) made by Nippon Pelnox Corporation
phenolic resin: “Phenolite VH-4150” (trade name) made by Dainippon Ink and Chemicals Inc.
cyanate resin: “AroCyM-30” (trade name) made by Asahi Chiba Co., Ltd.
carbon black: “R-390” (trade name) made by Toyo Carbon, Co., Ltd.
diffusing agent: “Plysurf S-208F” (trade name) made by Dai-Ichi Kogyo Seiyaku Co., Ltd.

TABLE 2

| | Thermal | Linear Thermal | Dielectric | Dielectric | Withstand |
|---|---|---|---|---|---|
| Sample | Conductivity | Expansion | Constant | Loss | Voltage [AC] |
| No. | (W/m · K) | Coefficient (ppm/° C.) | 1 MHz | 1 MHz (%) | (KV/mm) |
| 1 | 0.52 | 45 | 3.5 | 0.3 | 8.1 |
| 2 | 0.87 | 32 | 4.7 | 0.3 | 10.1 |
| 3 | 1.2 | 26 | 5.8 | 0.3 | 16.5 |
| 4 | 2.8 | 21 | 6.1 | 0.2 | 15.5 |
| 5 | 1.2 | 12 | 3.8 | 0.2 | 18.7 |
| 6 | 1.5 | 11 | 3.7 | 0.2 | 17.1 |
| 7 | 4.2 | 24 | 8.1 | 0.4 | 15.2 |
| 8 | 5.5 | 10 | 6.8 | 0.3 | 17.4 |
| 9 | 5.8 | 18 | 7.3 | 0.3 | 19.3 |
| 10 | 2.2 | 7 | 3.5 | 0.2 | 18.2 |
| 11 | 4.1 | 1 | 7.7 | 0.5 | 13.2 |
| 12 | 3.8 | 15 | 7.3 | 0.2 | 14.5 |

When fabricating a first mixture that makes up the electrically insulating substrate, first, a predetermined amount only of a mixture in paste form that has been mixed to a composition shown in Table 1 is dropped onto a mold-release film. This paste mixture is created by mixing an inorganic filler and a liquid thermosetting resin for about 10 minutes in a mixer. The mixer that is used receives inorganic filler and liquid thermosetting resin in a vessel with a predetermined capacity and revolves as it spins the vessel, and is capable of obtaining a sufficiently diffused state even if the mixture has a relatively high viscosity. For the mold-release film, a 75 μm thick polyethylene terephthalate film with a surface that has been subjected to a silicon release agent is treated.

Next, a mold-release film is further stacked on the paste mixture on the mold-release film and these are pressed to a thickness of 200 μm by a compressing press to obtain a sheet shaped mixture. It should be noted that a favorable sheet shaped mixture also can be obtained by placing a slurry mixture with an even lower viscosity on the mold-release film and forming a sheet using a doctor blade technique.

If amorphous SiO₂ is used as inorganic filler, then the linear expansion coefficient is 12 ppm/° C., and this is closer to that of a silicon semiconductor (linear expansion coefficient 3 ppm/° C.). Consequently, an electrically insulating substrate with amorphous SiO₂ as inorganic filler is preferably used as a flip chip substrate to which semiconductors are directly mounted.

Also, if SiO₂ is employed as inorganic filler, then an electrically insulating substrate with a low dielectric constant of 3.4 to 3.8 is obtained. SiO₂ is advantageous because it has a low specific weight. Modules with internally packaged circuit components that use SiO₂ as inorganic filler are preferably used as high frequency modules such as portable telephones.

Next, with the method of fabricating the transfer mold material shown in FIG. 1A, a copper foil in which a 70 μm thick electrolytic copper foil and a 9 μm thick electrolytic copper foil are laminated with chrome plating interposed between them is prepared as a detachment layer. The detachment layer side of the 9 μm thick copper foil is not processed, and the surface side is made of a silane coupling material layer, a chromate anti-oxidizing layer, or an Ni—Zn plating layer for the purpose of preventing it from rusting. Then, a photolithography technique (lamination of a dry film resist (DFR), pattern exposure, developing, etching with ferric chloride aqueous solution, and stripping the DFR with sodium hydroxide aqueous solution) is performed from the 9 μm copper foil side, thereby fabricating a transfer mold material in which copper foil wiring patterns are formed. It should be noted that in this working example a copper foil film was used as the detachable carrier sheet, but a resin film such as polyester or the like also can be used.

Next, with the method for fabricating the substrate with carrier sheet shown in FIG. 1B, an electrically insulating sheet made of a B-stage (semi-cured or partially cured) epoxy resin is prepared and heated at 120° C., after which the transfer mold material is pressed down against it and adhered at a pressure of 30 kg/cm², thereby obtaining the substrate with carrier sheet.

Then, with the method of fabricating the semiconductor device shown in FIG. 1E, a TEG (test element group) bare semiconductor element is prepared, and using an Au wire, stud bumps with a thickness of 50 μm are formed. At the same time, a composite sheet with excellent fluidity made of silica filler and an epoxy resin is prepared as an NCF.

The electrically insulating substrate on which wiring patterns have been formed is placed on a heating stage, and once it has been aligned with the semiconductor element, the carrier sheet is mechanically removed as shown in FIG. 1C, and then heat and pressure (150° C., 80 g/bump) are immediately added to join the bumps and the copper terminal electrodes. At the same time, the film 108 is cured so as to mechanically reinforce the bump connection portions.

The initial connection resistance of the bumps of the semiconductor device obtained in this fashion was evaluated. For comparison, three semiconductor devices in which the wiring patterns that are formed in the substrate are (1) copper foil wiring patterns to which an anti-oxidizing film has been formed, (2) non-processed copper foil wiring patterns formed by a subtractive technique, and (3) copper foil wiring patterns formed in the substrate that have been subject to non-electrolytic Ni—Au plating, respectively, were prepared.

The bump connection resistances were as follows.

| | | |
|---|---|---|
| (1) copper foil wiring with anti-oxidant film: | 100 to 500 | mΩ |
| (2) non-processed copper foil wiring obtained by | 100 to 1000 | mΩ |
| a subtractive process: | | |
| (3) non-electrolytic Ni—Au plated copper foil | 20 to 25 | mΩ |
| wiring: | | |
| (4) present working example (non-processed copper | 10 to 15 | mΩ |
| foil immediatelt after carrier stripping) | | |

As can be understood from the above results, the configuration of this working example clearly obtains an initial connection resistance that is superior to that of the copper terminal electrodes that have been Au plated.

On the other hand, in a case where packaging is carried out simply using non-processed copper foil wiring, the connection resistance is not only high but there is also significant variation, as is clear from the results of (2).

It should be noted that the same trend and resistance values were obtained for the bump connection resistance after the semiconductor element 201 was buried under the electrically insulating substrate 206.

Next, a solder reflow test and a temperature cycle test were performed in order to evaluate the reliability of the semiconductor device that was fabricated. The solder reflow test was performed using a belt-type reflow tester to repeat a ten second cycle for ten times at a maximum temperature of 260° C. The temperature cycle test was performed by repeating 200 cycles of a process in which the device was held at a temperature of 125° C. for 30 minutes and then held at a temperature of −60° C. for 30 minutes.

After both the solder reflow test and the temperature cycle test, the module with internally mounted circuit components according to this working example did not exhibit cracking, and no particular abnormalities were identified even with an ultrasonic detector. These results confirm that the bump connection portions of the semiconductor element were adhered firmly.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. A metal wiring board, wherein metal wiring buried in a surface layer of an electrically insulating substrate is adhered to a carrier sheet that covers the metal wiring, that can be mechanically detached, and that prevents oxidation of the metal wiring.

2. The metal wiring board according to claim 1, wherein a surface of the metal wiring that is in contact with the carrier sheet has not been subject to an anti-oxidizing process.

3. The metal wiring board according to claim 1, wherein a surface of the metal wiring buried in a surface layer of the electrically insulating substrate has been subjected to an anti-oxidizing process.

4. The metal wiring board according to claim 1, wherein the carrier sheet is a metal sheet or a resin sheet.

5. The metal wiring board according to claim 4, wherein the resin sheet is at least one resin film selected from the group consisting of polyimide, polyethylene terephthalate, polyethylene naphthalate, polyphenylene sulfite, polyethylene, polypropylene, and a fluoride resin, and the metal sheet is copper foil.

6. The metal wiring board according to claim 1, wherein the thickness of the carrier sheet is in a range of 30 to 100 μm.

7. The metal wiring board according to claim 1, wherein the metal wiring is copper foil, a detachable layer is formed between the carrier sheet and the metal wiring, and the detachable layer is a chrome plated layer.

8. A semiconductor device, including a structure wherein a metal terminal electrode buried in an electrically insulating substrate is electrically connected to a protruding electrode on a semiconductor element, the protruding electrode has a structure with a tip that is flattened by mounting the semiconductor element to the substrate, and the portion where the substrate and the semiconductor element are connected is reinforced by an insulating resin structure and formed into a single unit therewith.

9. The semiconductor device according to claim 8, wherein a surface of the metal terminal electrode has not been subjected to an anti-oxidizing process.

10. The semiconductor device according to claim 8, wherein the insulating resin structure is a resin film.

11. The semiconductor device according to claim 8, wherein the insulating resin structure is made of a resin component that includes inorganic filler and at least an epoxy resin.

12. The semiconductor device according to claim 8, wherein the semiconductor element is buried in another substrate.

13. The semiconductor device according to claim 8, wherein no gap exists between the semiconductor element and the substrate when the semiconductor element is buried in the substrate.

14. The semiconductor device according to claim 8, wherein the insulating resin structure and the substrate burying the semiconductor element are both made of a composition that includes inorganic filler and resin.

15. The semiconductor device according to claim 8, wherein the protruding electrode formed on the semiconductor element is formed through plating.

16. The semiconductor device according to claim 8, wherein the metal wiring pattern is copper foil, a detachable layer is formed between the carrier sheet and the wiring pattern, and the detachable layer is a chrome plated layer.

17. A method of manufacturing a semiconductor device, comprising:
bringing a transfer material in which a metal wiring pattern is formed on a carrier sheet into contact with an electrically insulating substrate, and burying the metal wiring pattern in the substrate;
preparing an insulating resin structure for reinforcing a portion where the metal wiring pattern is connected to a protruding electrode formed on a semiconductor element;
stripping away the carrier sheet; and
a semiconductor mounting step of applying heat and pressure to the metal wiring pattern that is exposed in the stripping step to bring the tip of the protruding electrode into contact with the metal wiring pattern via the insulating resin structure, and subsequently applying heat and pressure to the wiring pattern and the protruding electrode to flatten the tip and connect the wiring pattern and the protruding electrode.

18. The method of manufacturing a semiconductor device according to claim 17, wherein the carrier sheet is a metal sheet or a resin sheet.

19. The method of manufacturing a semiconductor device according to claim 18, wherein the resin sheet is at least one resin film selected from the group consisting of polyimide, polyethylene terephthalate, polyethylene naphthalate, polyphenylene sulfite, polyethylene, polypropylene, and a fluoride resin, and the metal sheet is copper foil.

20. The method of manufacturing a semiconductor device according to claim 19, wherein the carrier sheet is copper foil, the metal wiring pattern is copper foil, and a detachable layer is formed between the carrier sheet and the wiring pattern as a chrome plated layer.

21. The method of manufacturing a semiconductor device according to claim 17, including, after the semiconductor mounting step, a step of burying the semiconductor element in a substrate made of a composition including inorganic filler and resin.

22. The method of manufacturing a semiconductor device according to claim 17, wherein the protruding electrode is formed by plating.
